(19) United States
(12) Patent Application Publication
(10) Pub. No.: US 2007/0069605 A1
(43) Pub. Date: Mar. 29, 2007

(54) Micro electromechanical device with stress and stress gradient compensation

(75) Inventors: Gerrit Klaasse, Lieren (NL); Hendrikus Tilmans, Maasmechelen (BE)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: Interuniversitair Microelektronica Centrum (IMEC), Leuven (BE)

(21) Appl. No.: 11/453,697

(22) Filed: Jun. 15, 2006

Related U.S. Application Data
(60) Provisional application No. 60/691,224, filed on Jun. 15, 2005.

(30) Foreign Application Priority Data
Jun. 16, 2005 (EP) 05105336.2

(51) Int. Cl. H02N 1/00; H01L 41/00

(52) U.S. Cl. 310/309; 310/311

(57) ABSTRACT

Micro electromechanical devices and methods for designing such devices are disclosed. An example micro electromechanical device includes at least two anchors. The example device also includes a floating element. The floating element extends between the at least two anchors and includes a predetermined reference portion. In at least one predetermined state during operation of the device, the reference portion is located within a predetermined reference plane. The floating element includes at least two flexible sections, where the at least two flexible sections each extends between the reference portion and a respective one of the anchors. In the example device, at least two of the at least two flexible sections include respective stress relieving elements. The stress relieving elements enable deflection of the floating element as a result of a stress gradient. The stress relieving elements are provided at predetermined locations between the respective anchors and the reference portion, where the predetermined locations are selected such that the reference portion is substantially located within the predetermined reference plane in the at least one predetermined state of the device.

### CROSS REFERENCE TO RELATED APPLICATIONS

This application claims priority benefits under 35 U.S.C. § 119(e) to U.S. Provisional Patent Application No. 60/691,224, filed on Jun. 15, 2005. This application also claims priority benefits under 35 U.S.C. § 119(a) to European Patent Application 05105336.2, filed on Jun. 16, 2005. U.S. Provisional Patent Application 60/691,224 and European Patent Application 05105336.2 are incorporated herein by reference in their entirety.

### BACKGROUND

I. Field

This disclosure relates to micro electromechanical (MEM) devices.

II. Description of Related Art

MEM devices generally include a floating element, such as, for example, an actuator beam or a membrane. Such MEM devices can be used for a variety of functions, e.g., as an electrode of a variable capacitor, as a switching means, or any number of other functions. Actuation of such MEM devices can be accomplished in a number of fashions. For example, actuation may be accomplished electrostatically, piezoelectrically, thermoelectrically or electromagnetically. The floating element (e.g., actuator beam) typically extends between two or more anchors and includes a predetermined reference portion. The reference point is used for reference purposes in accordance with the function of the MEM device, and flexible sections suspend the reference portion on the anchors. Such floating elements may be fabricated using thin film deposition techniques and can, therefore, be subject to residual stresses and stress gradients. Deposition conditions can be adjusted to control these stresses. However, process uncertainties still lead to unpredictable stresses in such floating elements. In addition, the temperature(s) to which a MEM device is exposed to after fabrication can vary, which may result in thermal stresses, which can also result in variability in the properties and/or operation of such MEM devices.

One technique for making MEM devices that are less sensitive to such stresses is the introduction of corrugations on the floating elements (actuator beam). The corrugations function as springs to release the average stress. However, such corrugations introduce an initial deflection of the floating element due to stress gradients. This initial deflection strongly influences the operating characteristics of the device, such as, for example, the actuation voltage in case of electrostatic actuation. These influences are undesirable, particularly when the power supply for providing the actuation voltage has limited capacity, e.g. for RF-MEM devices that are used in battery powered wireless communication systems.

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods, which are given by way of example and meant to be illustrative, not limiting in scope. In various embodiments, one or more of the above-described problems have been reduced or eliminated, while other embodiments are directed to other improvements.

Micro electromechanical (MEM) devices that include stress relieving elements for releasing stress and thereby compensate for the effects of stress gradients are disclosed. An example MEM device includes a floating element that extends between at least two anchors. The floating element has a predetermined reference portion, which, in at least one predetermined state of the device, when in use, is located within a predetermined reference plane. This reference plane is chosen in view of the desired characteristics of the device when used in the least one state.

The floating element includes at least two flexible sections that each extend between the reference portion and respective ones of the anchors. At least two of the at least two flexible sections each include a respective stress relieving element. The stress relieving elements release stress and cause deflection of the floating elements as a result of a stress gradient. The location of these stress relieving elements on their respective flexible sections is selected between the reference portion and the respective anchor, such that, in operation, the deflection of the floating element at the reference portion is located in the predetermined reference plane in the predetermined state of the device.

The predetermined state of the device in which the reference portion is to be located in the reference plane may, for example, be an initial state, for example, a state in which no actuation forces are applied to the floating element. Alternatively, the predetermined state may be another state of the MEM device, for example, a state in which a given actuation force is applied. In certain embodiments, the predetermined reference plane may be substantially parallel to the plane in which the reference portion, or the whole floating element, generally extends.

In current devices using corrugations, such corrugations are generally placed physically near the anchor points. Location of the corrugations near the anchor points is done so as to reduce the adverse impact of the corrugations on the strength of the floating element. However, this makes such devices highly sensitive to stress gradients.

In the example device, the location(s) of the stress relieving elements is(are) determined in order to improve control of the effects of stress gradients caused, for example, by deflection of the floating element. For instance, the respective locations of the stress relieving elements are selected such that deflections are reduced at the reference portion as compared with prior approaches. By appropriately placing the stress relieving elements, the effects of both average stresses and stress gradients may be substantially cancelled out for at least the predetermined state. Accordingly, floating elements, such as for example MEM actuator beams or membranes can be designed with properties substantially independent to process variations and to thermally induced stresses.

### BRIEF DESCRIPTION OF THE DRAWINGS

Example embodiments are illustrated in referenced figures of the drawings. It is intended that the embodiments and figures disclosed herein are to be considered illustrative rather than restrictive.

FIG. 1 shows a cross-sectional view and the influence of average stress and stress gradient for a clamped-clamped beam configuration (FIG. 1A) and clamped-free beam configuration (FIG. 1B);

FIG. 2 shows a schematic top view of a corrugation, placed in a clamped-clamped beam (FIG. 2A) and the corresponding mechanical model in cross-sectional view (FIG. 2B);

FIG. 3 shows a schematic top view of a designed RF-MEMS switch with zero initial deflection according to the invention;

FIG. 4 shows optical photographs of fabricated electrostatically actuated beams without corrugations (FIG. 4A), with corrugations placed in closed physical proximity with anchor points (FIG. 4B) and with corrugations placed in accordance with the techniques described herein (FIG. 4C); and

FIG. 5 shows profiles of the three beams of FIG. 4, measured with white light interferometry.

### DETAILED DESCRIPTION

In one embodiment of an example MEM device, a floating element may be actuated between an up-state and a down-state, where the reference portion of the floating element is substantially within the reference plane when the floating element is in the up-state. In this particular embodiment, the locations of the stress relieving elements on their respective flexible portions are selected such that deflection of the floating elements at the reference portion is reduced in the up-state, as compared with prior approaches (e.g., devices using corrugations located near the anchor points) or devices that do not include stress relieving elements.

In the example device, the floating element may be actuated by means of an actuator that is located in an actuation plane at a predetermined height below the reference plane. The position of the actuator in the actuation plane may be underneath the reference portion, when the lowest actuation force is desired, or offset, as has for example been described in U.S. patent application Ser. No. 11/317,370, which is herein incorporated by reference. The example device is, for example, suitable for switching an RF signal line. Accordingly, the actuator may be part of the RF signal line. Alternatively, the actuator may be a separate actuator.

In the example device, a dielectric layer with a predetermined thickness may be provided on top of the actuator to control a capacitance of the device in the down-state. Further, a conductive layer may be deposited on top of the dielectric layer to improve contact, as described, for example, in European Patent Application No. 03020159.4 published as EP-A-1398811 and in U.S. patent application Ser. No. 11/317,370, both of which are incorporated by reference herein.

The stress relieving elements of the example MEM device may be formed by corrugations or any other equivalent means known to those working in this area. Such corrugations may be substantially any structure that provides a spring-like functionality. Such a structure may be an essentially planar structure or, alternatively, may be a three-dimensional structure.

In the example MEM device, the flexible sections have a constant cross-section and each stress relieving element is located substantially in the middle of its respective flexible section. In this context, constant cross-section means that the height and the width of the section is substantially the same over its entire length. This embodiment has the advantage of being simple in design. In certain alternative embodiments, the cross-section surface can be constant, rather than the cross-section itself.

In other embodiments the width and/or height of the flexible sections may vary along the longitudinal direction of the flexible sections. A varying width is generally easier to produce for a layered structure than a varying height. In certain embodiments, the flexible sections are multi-layer structures. For such multi-layer structures, a varying height may be easily produced, although substantially discrete height variations are typical for thin film processing.

In yet another embodiment of a MEM device, the floating element includes two flexible sections on opposite sides of a reference portion. This embodiment also has the advantage of being simple in design, especially in combination with the features of the foregoing paragraph. However, embodiments with more flexible sections, non-constant cross sections and/or non-centered stress relieving elements are also possible. In embodiments of MEM devices that include more than two flexible sections, the additional flexible sections (in excess of two) may or may not include respective stress relieving elements.

The reference portion of the floating elements may be a rigid portion or a flexible portion of the elements. The reference portion may have a predetermined length, such as for making a suitable contact with a given electrode of the device. Alternatively the reference portion may be a discrete point on the floating element.

Methods for designing MEM devices, such as the devices described herein, are also disclosed. An example method includes determining the location of the stress relieving elements on the floating elements in such a way that the reference portion is substantially located within the reference plane in the predetermined state (as described above). In situations where substantially no deflection of the reference portion is desired, the method includes modeling each floating section as a bridge between two fixed points, one being the anchor and the other being the connection between the floating section and the reference portion. In this way, the locations of the respective stress relieving elements may be easily determined.

As those of skill working in this area will appreciate, a key element in many MEM devices is the actuator. Such actuators, for example, may transform an electrical signal into a mechanical movement. Accordingly, as discussed above, a MEM device generally includes a beam, a membrane, or like element (e.g., a floating element) that overhangs the actuator. The actuator is actuated using, for example, electrostatic, piezoelectric, thermoelectric or electromagnetic actuation. In the embodiments shown in the Figures and described herein, the floating element takes the form of a beam 10, which may be referred to as an actuator beam. It will be understood that other floating elements may also be used in place of such actuator beams.

The beams 10 are fabricated using thin film deposition techniques and, therefore, are subject to the effects of residual stresses and stress gradients. The effects of such stresses and stress gradients may be controlled, in part, by varying the deposition conditions. However, process uncertainties may still lead to unpredictable stresses in the beam. This may be particularly true for multilayer beams. Such multilayer beams may be operated, for example, as electro-thermal and/or piezoelectric beams. In addition, the temperatures the MEM device is exposed to after fabrication may vary (such as due to additional processing and/or operation of the MEM device). Such variations in temperature result in thermal stresses. All of these different stresses may lead to varying properties of the actuator beam 10. These varying properties are compensated for and/or controlled by the selection of the respective locations for the stress relieving points.

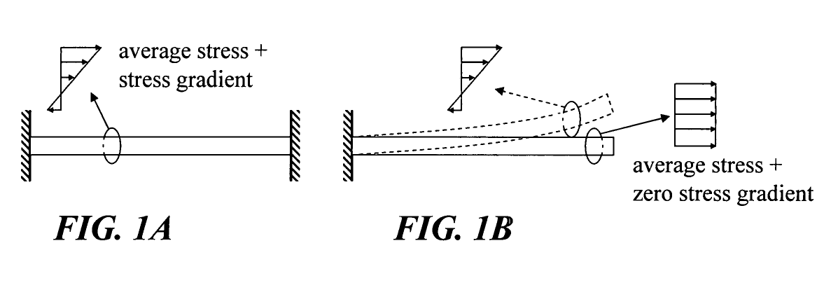

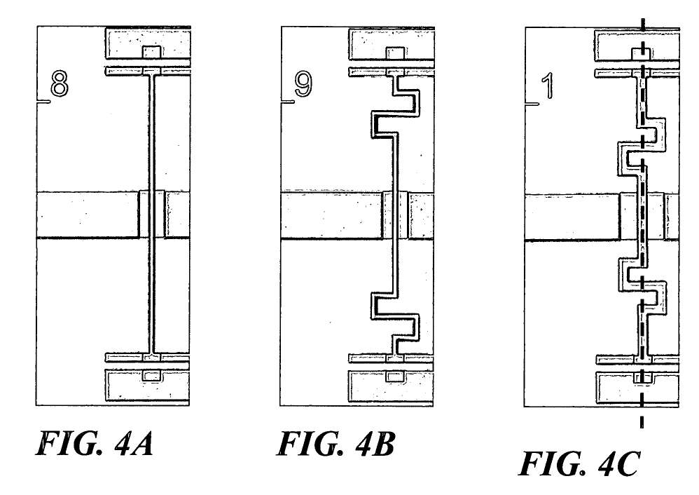

FIG. 1 illustrates two basic beam configurations that are commonly used in MEM devices. These configurations are a clamped-clamped beam configuration (FIG. 1A) and a clamped-free beam configuration (FIG. 4B). The clamped-free beam configuration shows initial deflection when a stress gradient is present, but an average stress has no substantially no influence on the stiffness of the beam. The stiffness of a clamped-clamped beam, in comparison, is strongly influenced by an average stress, but has substantially no initial deflection due to a stress gradient. The effects of beam stiffening and initial deflection strongly influence the physical and operating characteristics of such actuator beams, particularly the actuation voltage. This influence is undesired, especially when the amount of power used for supplying the actuation voltage is limited, e.g., for RF-MEMS components in battery powered wireless communication systems, as was previously discussed.

In order to make the actuator beam 10 less sensitive to such stresses, a beam including desirable features of both beam configurations may achieved by using a clamped-clamped beam 10 with stress relieving elements 5, where stress relieving elements 5 are, for example, corrugations. These stress relieving elements 5 function as springs and release the average stress, but cause an initial deflection of the beam 10 as a result of stress gradients. In order to compensate for this initial deflection at the reference point or area 3 (e.g., the portion of the beam 10 which is actuated) the location of the stress relieving elements 5 is determined such that a reference portion 3 of the beam 10 in at least one predetermined state is within a predetermined reference plane. For example, if the initial deflection of the reference portion 3 is to be reduced, the predetermined state is the initial state of the device when no actuation forces are acting on the reference portion 3 and the predetermined reference plane is the plane in which the beam 10 mainly extends or the plane in which its anchors 1, 2 are located.

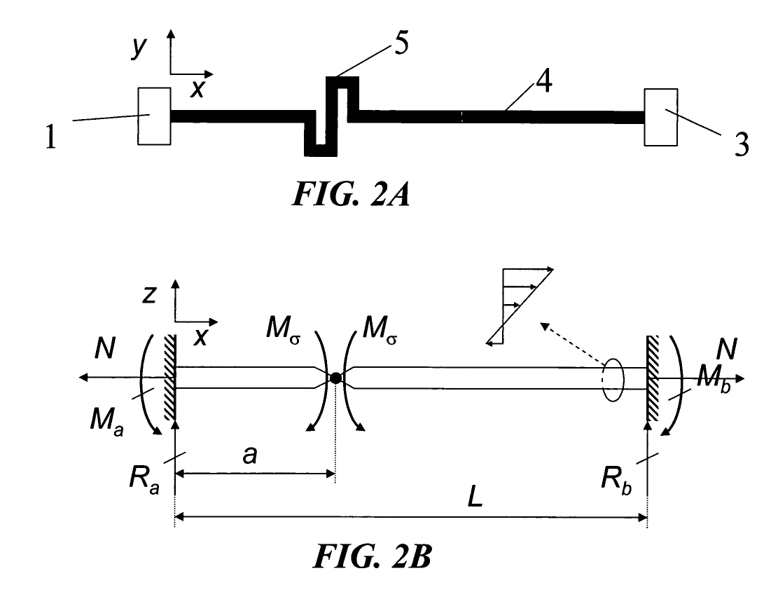

In order to determine the location of the stress relieving elements 5, a mechanical model may be used. In such a model, the beam 5 is modeled as a number of flexible sections 4 commonly connected to the reference point 3, which is treated as a fixed point in the same way as an anchor point 1, 2. When a corrugation 5 is placed in a clamped-clamped beam 10, the stiffness of the beam is locally disturbed. One possible design of a corrugation 5 in a clamped-clamped beam is shown in FIG. 2A. The corrugation 5 can be modeled as a hinge (see FIG. 2B), which releases the stress and allows locally discontinuous torsion of the beam 10. Accordingly, the stiffness of the beam 5 is reduced because of this local torsion. The stiffness, however, is less dependent on the residual stress in the beam in such a configuration.

In the following analysis, it is assumed that each floating section 4 has a continuous cross-section (e.g., a constant width and height). For floating sections 4 and/or beams 10 that do not have such a continuous cross-section, additional parameters may have to be taken into account. Further, it is assumed that average stresses are substantially fully released in the corrugation 5, making the normal forces N equal to zero. The bending moments M_{σ} in the beams 10 originate from a non-uniform stress distribution over the thickness of the beam 10 and act to the left and to the right of the hinge (corrugation 5). The bending moments have the same magnitude, but act in opposite rotational directions. The reaction moments Mₐ and M_{b} are equal to M_{σ}, as it is the case for a clamped-clamped beam without a hinge. (E.g., If there is no hinge, the moments cancel out over the entire length of the beam and do not cause any deflection and reaction forces).

The applied bending moments M_{σ} cause reaction forces R_{A} and R_{B} at the clamped edges 1, 3, which are given by:

$${R}_{A} = - {R}_{B} = \frac{3 {M}_{σ}}{2} [ \frac{2 a - L}{a ( L - a )} ]$$

In order to obtain a substantially equivalent behavior at the anchor points 1, 3 as for beams without a hinge, the reaction forces R_{A} and R_{B} should be essentially equal to zero. This is the case when the hinge is placed in the middle of the beam, e.g., when a=L/2. In this situation, the beam 10 has reaction forces equal to zero and reaction moments equal to M_{σ}, when the hinge is placed at a=L/2. This technique can be used to design an actuator beam 10 that is substantially insensitive to both residual stresses and stress gradients, as is described below.

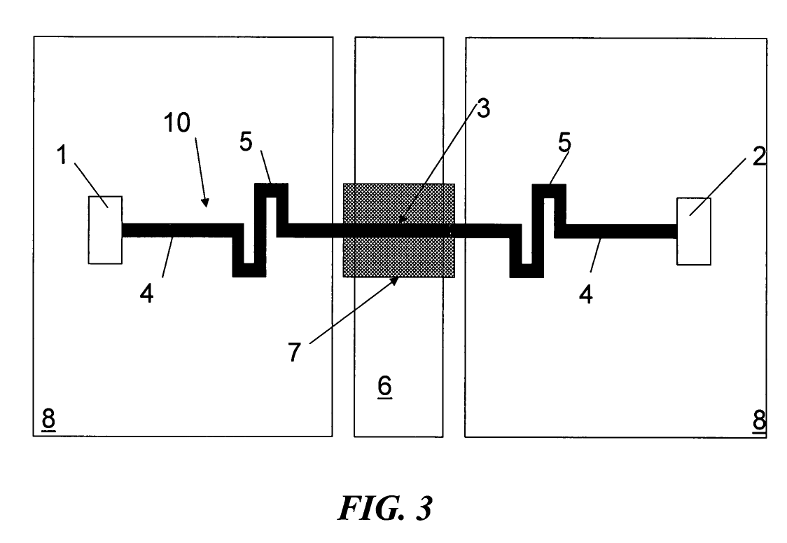

Based on the foregoing, actuator beams 10 may be designed which are substantially insensitive to both residual stresses and stress gradients. As an example, the design of an electrostatically actuated RF-MEMS switch is described here with reference to FIG. 3. For instance, FIG. 3 illustrates an electrostatically actuated RF-MEMS switch including a beam 10 suspended over an RF-signal line 6. In the device illustrated in FIG. 3, a dielectric 7 is provided on top of the RF-signal line 6 in an actuation area. The beam 10 extends between two anchors 1, 2, provided on RF-ground layers 8. Additional possible features of such an RF-MEMS switch are described in European Patent Application No. 03020159.4, which was published as EP-A-1398811, and in European Patent Application No. 05103893.3, both of which are hereby incorporated by reference.

Using the mathematical approach described above, the RF-MEMS switch of FIG. 3 is designed such that there is substantially no initial deflection at the reference area. For this embodiment, the reference area is reduced to a reference point 3, as there is only a single point, the reference point 3, where an initial deflection of zero is desired. As a result, the beam 10 is designed with two basic segments 4 which extend from the reference point 3 up to their respective anchors 1, 2. The reference point 3, in this particular embodiment, is the center of the beam 10 and also the center of the actuation area. In this embodiment, the actuation area is the overlap of the beam 10 with the RF-signal line 6.

If a beam (such as the beam 10 shown in FIG. 3) includes of a series of basic segments where a=L/2 (as shown in FIG. 2), such a beam will have substantially zero deflection at all the points where the basic segments 4 are connected. Because, in this example, the beam 10 of FIG. 3 has a constant cross-section, the mathematical technique discussed above results in the corrugations 5 being placed in the middle of their respective sections 4. This design differs from current MEM devices, where corrugations are placed in close proximity to the anchor points.

The same mathematical technique can be used for designing beams or structures that include a reference portion or area rather than a reference point. This reference portion or area can be flexible or rigid. Such an approach may also be used for implementing off-center reference portions or points and/or structures having more than two flexible sections 4, where at least some of the flexible sections 4 do not include a corrugation 5.

FIGS. 4A-4C are photographs of electrostatically actuated beams. In the structures of FIGS. 4A-4C, an aluminum layer of 400 nm thick was used as a bottom electrode. On top of the bottom electrode, 200 nm of AlN was deposited as a dielectric layer to provide electric isolation between the bridge and the bottom electrode. A 1 μm thick aluminum beam with an average tensile stress of 200 MPa (calculated from wafer bow measurement of a full wafer) and a stress gradient of 70 MPa/μm (calculated from cantilever deflection measurements) was deposited on top of a 2 μm thick polyimide sacrificial layer. Using this process, beams without corrugations (FIG. 4A), beams with corrugations placed in close proximity to anchor points (FIG. 4B) and beams with corrugations placed according to the techniques described herein (FIG. 4C) were produced.

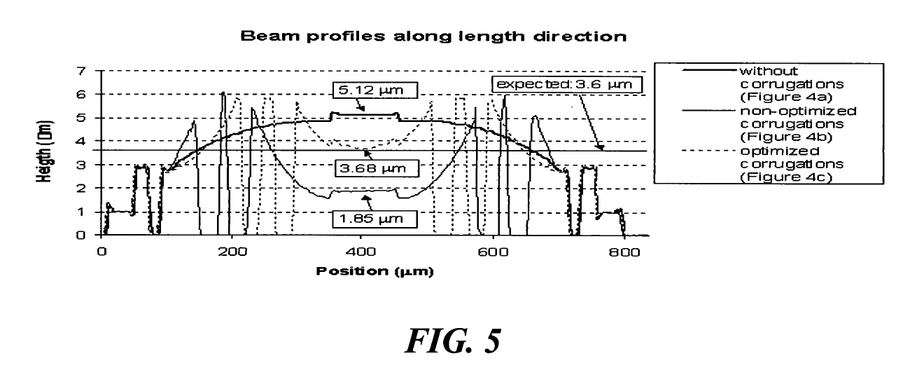

The profiles of these beams after fabrication were measured with white light interferometry along the length of the beams, as indicated by the dotted line in FIG. 4C. The results of these measurements are illustrated by the graph shown in FIG. 5.

FIG. 5 shows the measured values for the height of the beam above the bottom electrode. The height is the sum of the thicknesses of the deposited layers. If substantially no planarization effects occur during the processing of the sacrificial layer, this value for this particular example is 3.6 μm.

The initial deflection of the beam without corrugations (FIG. 4A) shows a positive initial deflection. This was unexpected from the measured average stress value, but the stress in the beam on top of the sacrificial layer is likely to be different from the stress as measured by a wafer-bow measurement on a full wafer. The beam with corrugations located in close proximity to the anchors (FIG. 4B) shows a large initial deflection downwards, as expected.

The beam with the corrugations placed using the techniques described herein (FIG. 4C) has an initial deflection that is very close to the expected value, meaning that there is substantially zero initial deflection. This shows that the placement of corrugations in a clamped-clamped beam can be done such that the stress is efficiently released and the stress gradient does not influence the initial deflection at the actuation area of the beam.

### CONCLUSION

While a number of aspects and embodiments have been discussed above, it will be appreciated that various modifications, permutations, additions and/or sub-combinations of these aspects and embodiments are possible. It is therefore intended that the following appended claims and claims hereafter introduced are interpreted to include all such modifications, permutations, additions and/or sub-combinations as are within their true spirit and scope.

What is claimed is:

1. A micro electromechanical device comprising:
at least two anchors;
a floating element including:
a predetermined reference portion, the floating element extending between the at least two anchors, wherein, in at least one predetermined state during operation of the device, the reference portion is located within a predetermined reference plane; and
at least two flexible sections, the at least two flexible sections each extending between the reference portion and a respective one of the anchors, wherein at least two of the flexible sections include respective stress relieving elements, wherein the stress relieving elements enable deflection of the floating element as a result of a stress gradient, the stress relieving elements being provided at predetermined locations between the respective anchors and the reference portion, wherein the predetermined locations are selected such that the reference portion is substantially located within the predetermined reference plane in the at least one predetermined state of the device.

2. The micro electromechanical device of claim 1, wherein, in operation, the floating element is actuated between an up-state and a down-state such that the reference portion is substantially within the reference plane in the up-state.

3. The micro electromechanical device of claim 2, further comprising an actuator for actuating the floating element, the actuator being located in an actuation plane at a predetermined height below the reference plane.

4. The micro electromechanical device of claim 3, wherein the actuator is included in an RF signal line.

5. The micro electromechanical device of claim 3, further comprising a dielectric layer disposed on top of the actuator, the dielectric having a predetermined thickness for establishing a given capacitance of the device in the down-state.

6. The micro electromechanical device of claim 5, further comprising a conductive layer disposed on top of the dielectric layer.

7. The micro electromechanical device of claim 1, wherein the stress relieving elements each comprises a corrugation.

8. The micro electromechanical device of claim 1, wherein each flexible section has a constant cross-section and each stress relieving element is located substantially in the middle of each respective flexible section.

9. The micro electromechanical device of claim 1, wherein the floating element comprises two flexible sections on opposite sides of the reference portion.

10. The micro electromechanical device of claim 1, wherein the reference portion is a reference point.

11. A method for designing a micro electromechanical device comprising a floating element extending between at least two anchor points, the floating element comprising a predetermined reference portion, which, in at least one predetermined state of the device in operation, is located within a predetermined reference plane, and at least two flexible sections which each extend between the reference portion and respective ones of the anchor points, at least two of the flexible section comprising a stress relieving element which enables deflection of the floating element as a result of a stress gradient, the method comprising:
determining locations for the stress relieving elements between the respective anchor point and the reference portion such that the reference portion is substantially located within the reference plane in the predetermined state.

12. The method according to claim 11, further comprising modeling each flexible section as a bridge between two fixed points, a first fixed point being the respective anchor point and a second fixed point being the connection of the respective flexible section with the reference portion.
